(19) United States
(12) Patent Application Publication
(10) Pub. No.: US 2004/0144993 A1
(43) Pub. Date: Jul. 29, 2004

(54) Lateral transistor

(75) Inventors: Fumitoshi Yamamoto, Tokyo (JP); Toshiyuki Ebara, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/459,489

(22) Filed: Jun. 12, 2003

(30) Foreign Application Priority Data
Jan. 28, 2003 (JP) P2003-018548

(51) Int. Cl. H01L 29/74

(52) U.S. Cl. 257/122

(57) ABSTRACT

It is an object to provide a lateral transistor which enables a current gain rate to change less, even if it is used over a long time.

In the lateral transistor according to the present invention, a polysilicon layer (14) is formed to cover a collector region (5) and a base region (4) on a LOCOS oxide film (a field insulating film) (12) from a collector region (5) to an emitter region (6). Furthermore, in order to connect electrically that polysilicon layer (14) and the emitter region (6) with each other, the polysilicon layer (14) and the emitter region (6) are connected with each other by a wiring (15).

### BACKGROUND OF THE INVENTION

1. Field of the Invention

The present invention relates to a lateral transistor, and more particularly, it relates to a structure of a lateral transistor that a current gain rate remains stable over a long time.

2. Description of the Background Art

Conventionally, lateral transistors are employed for manufactures such as automobiles, motors, fluorescent character displays, audio devices or the like.

Here, the lateral transistors mean transistors that an emitter, a collector and a base are formed in an identical surface of a substrate and an element parallel with a surface of a minority carrier flow injected from the emitter commands an action (for example, refer to FIG. 2 of Japanese Patent Application Laid-Open No. 5-36701 (1993)).

However, in the conventional lateral transistor, there is a problem that the current gain rate increases chronologically.

### SUMMARY OF THE INVENTION

It is an object of the present invention to provide a lateral transistor which enables a current gain rate to remain nearly stable over a long time.

The present invention relates to a lateral transistor that an emitter region, a collector region and a base region are formed on an identical main surface of a substrate.

According to the present invention, the lateral transistor includes a field insulating film and a conductor layer. The field insulating film is formed astride both on the collector region and on the base region. The conductor layer is formed on the field insulating film, covering the collector region and the base region through the field insulating film from the collector region to the side of the emitter region. Moreover, the emitter region and the conductor layer are electrically connected with each other.

An expansion of a depletion layer near a top surface of the base region can be controlled, and even if that lateral transistor is actuated over a long time, a nearly stable current gain rate can be obtained.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a drawing illustrating a sectional structure of a lateral transistor according to the present invention.

FIG. 2 is a plane view illustrating a structure of the lateral transistor according to the present invention.

FIG. 3 is a drawing illustrating a sectional structure of a lateral transistor having a conventional structure.

FIG. 4 is a drawing illustrating an appearance of a depletion layer and an electric flow in the lateral transistor having the conventional structure.

FIG. 5 is a drawing of an experimental data illustrating a chronological change of a current gain rate in the lateral transistor having the conventional structure.

FIG. 6 is a drawing illustrating an appearance of a depletion layer in the lateral transistor according to the present invention.

FIG. 7 is an expanded sectional view illustrating the other embodiment of the lateral transistor according to the present invention.

### DESCRIPTION OF THE PREFERRED EMBODIMENTS

The present invention is concretely described on the basis of drawings illustrating the preferred embodiment hereinafter.

<Preferred Embodiment>

FIG. 1 is a cross sectional view illustrating a structure of a lateral transistor according to the present preferred embodiment.

In FIG. 1, a N+ type embedded diffusion layer 2 and a P+ type isolation diffusion layer 3 are formed on a determined point in a surface of a P− type semiconductor substrate 1. Moreover, a base region 4 composed of a N type epitaxial layer is formed covering the P− type semiconductor substrate 1, the N+ type embedded diffusion layer 2 and the P+ type isolation diffusion layer 3.

Here, a P type isolation diffusion layer 9 is formed on an upper part of the P+ type isolation diffusion layer 3, and an isolation region is formed of the P+ type isolation diffusion layer 3 and the P type isolation diffusion layer 9.

Moreover, a collector region 5 which is a P type diffusion layer is formed in a determined region annularly in a plane view by injecting boron and so on and performing a thermal treatment at a temperature of 1100° C. or more after performing an oxidation treatment of hundreds nm to an inside of a surface of the base region 4 and performing a photolithography treatment.

Moreover, an emitter region 6 which is a P+ type diffusion layer is formed surrounded by the annular collector region 5. That is to say, as recognized from FIG. 1, the base region 4, the collector region 5 and the emitter region 6 are formed on an identical main surface of the semiconductor substrate 1.

Moreover, in a determined point of the base region 4, a N+ type diffusion layer 7 is formed for the purpose of lessening a contact resistance with a wiring 10, and in a determined point of the collector region 5, a P+ type diffusion layer 8 is formed for the purpose of lessening a contact resistance with a wiring 11.

Moreover, a LOCOS oxide film 12 which is a field insulating film is formed covering the base region 4, the collector region 5 and the P type isolation diffusion layer 9. Furthermore, a polysilicon layer 14 which is a conductor layer is formed, covering the collector region 6 and the base region 4 through the LOCOS oxide film 12 from the collector region 5 to the emitter region 6.

Moreover, an oxide film 13 which is an interlayer insulating film is formed covering that polysilicon layer 14, the LOCOS oxide film 12 and so on.

Here, in determined points of the oxide film 13, through opening parts (via holes) are formed, and by filling those opening parts with a conductor such as aluminum and so on, the wiring 10 is placed to connect with the N+ type diffusion layer 7, the wiring 11 is placed to connect with the P+ type diffusion layer 8 and furthermore, a wiring 15 is placed to connect with the emitter region 6.

Moreover, in the lateral transistor according to the present invention, the wiring 15 is also connected with the polysilicon layer 14, and the emitter region 6 and the polysilicon layer 14 are electrically connected with each other.

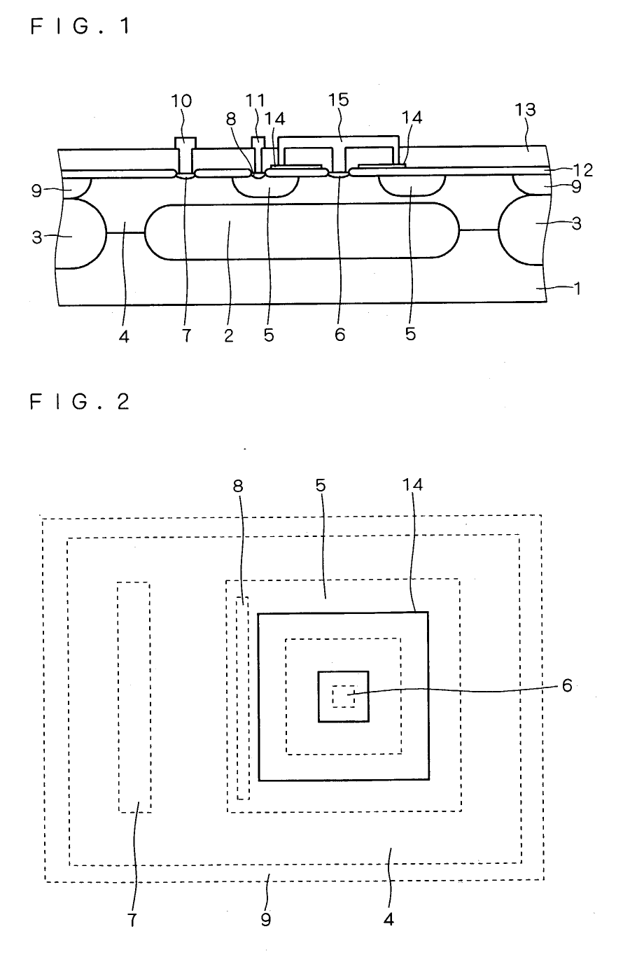

Besides, FIG. 2 is a plane view of the lateral transistor illustrated in FIG. 1. Here, shapes of the respective diffusion layers 4, 5, 6, 7, 8 and 9 are illustrated by dotted lines, and a shape of the polysilicon layer 14 is illustrated by full lines. Moreover, illustrations of the respective oxide films 12, 13 and the wirings 10, 11 and 15 are omitted.

As recognized from the composition described above, in the present invention, the polysilicon layer 14 is placed in a determined position of the LOCOS oxide film 12 and is electrically connected with the emitter region 6 by the wiring 15.

In the meantime, to describe an effect of the lateral transistor composed as described above, a lateral transistor having a conventional structure is described first.

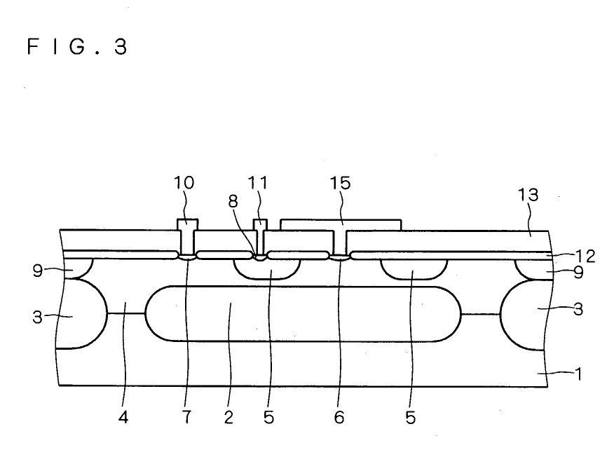

FIG. 3 is a cross sectional view illustrating the structure of the conventional lateral transistor. Here, in FIG. 3, codes which are identical with codes mentioned in the preferred embodiment signify identical or equal materials (parts).

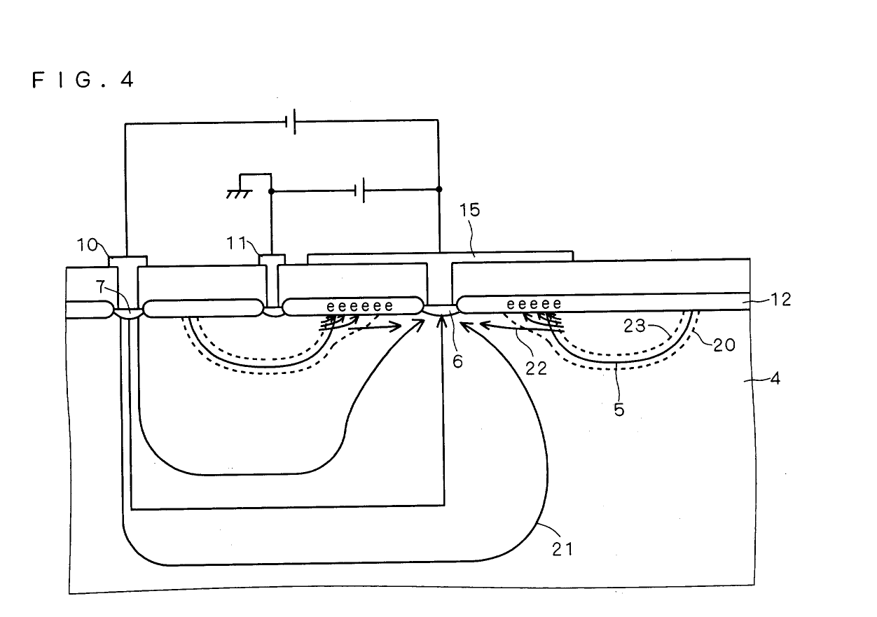

Moreover, FIG. 4 is a drawing illustrating an appearance of depletion layers 20 and 23 and electron flows 21 and 22 at a base-collector junction when the lateral transistor having the conventional structure illustrated in FIG. 3 is actuated.

As recognized from FIG. 4, in the lateral transistor having the conventional structure, by reason that thermally exited electrons (mentioned as hot carriers hereinafter) are drifted near the base-collector junction in an actuating condition, those hot carriers flow from the collector region to the base region (a code 22). At this time, part of the hot carriers is trapped in the LOCOS oxide film 12 near a surface of the base-collector junction under an influence of the wiring 15 which has a “+” potential.

Accordingly, an apparent potential near a top surface of the base region 4 and the collector region 5 lowers, and the depletion layer 20 at a side of the base region 4 expands near the top surface of that base region 4 and the depletion layer 23 at a side of the collector region 5 narrows near the top surface of that collector region 5 in the base-collector junction.

That is to say, according as the hot carriers are trapped in the LOCOS oxide film 12, an effective base region narrows, and it means that a base current (an electron flow 21) decreases gradually (increasing as for the current gain rate), thus it is impossible to provide the lateral transistor having a chronological stability.

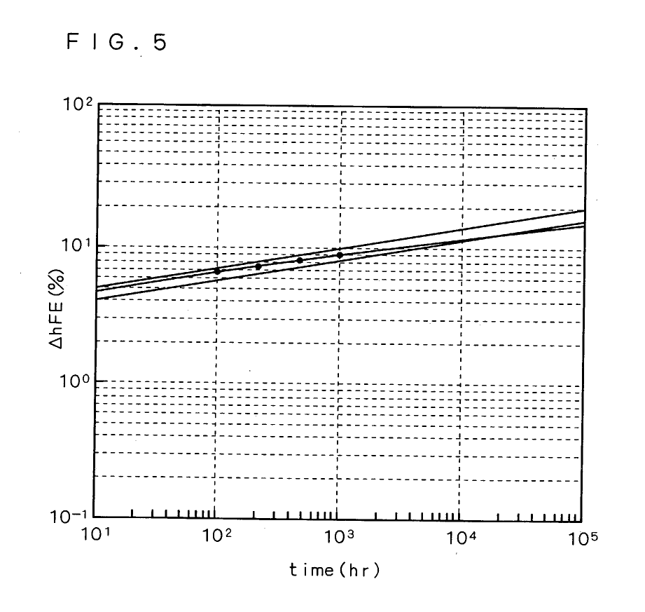

Besides, FIG. 5 is a drawing of an experimental data illustrating a chronological change of a current gain rate in the lateral transistor having the conventional structure, and as shown in FIG. 5, ten years later, the current gain rate increases approximately sixteen % as compared with a primary value.

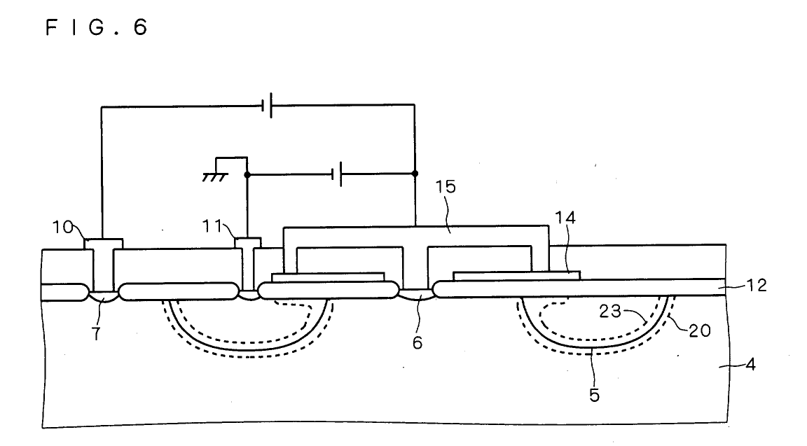

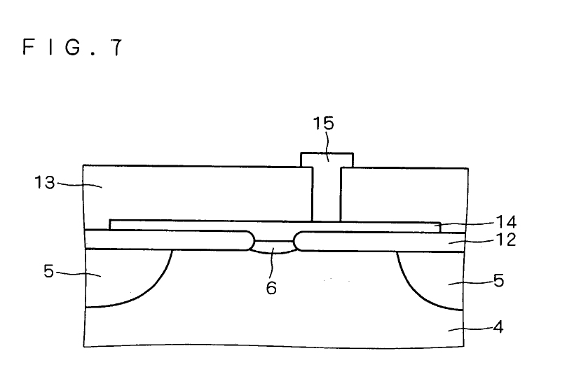

However, in the present invention, the polysilicon layer 14 is formed in a determined position, covering the collector region 5 and the base region 4 through the LOCOS oxide film 12, and that polysilicon layer 14 and the emitter region 6 are electrically connected with each other through the wiring 15, thus as shown in FIG. 6, an expansion of the depletion layer 20 near the top surface of the base region 4 according to an elapsed time can be controlled.

That is to say, the polysilicon layer 14 is acted as an electrode electrified to “+” which is an emitter potential in a condition in close proximity to the base region 4, thus even if the hot carriers are trapped in the LOCOS oxide film 12, an influence of the polysilicon layer 14 is stronger than a potential decrease near the top surface of the base region 4 according to the trapping, thus an expansion of the depletion layer 20 caused by the trapped hot carriers can be controlled.

Moreover, the polysilicon layer 14 is also formed on the collector region 5, thus the depletion layer 23 at the side of the collector region 5 expands more near the top surface of that collector region 5. According to this, there is a high probability that the hot carriers are trapped in the LOCOS oxide film 12 on the collector region 5, and thus they are not trapped in the LOCOS oxide film 12 on the base region 4 so much as compared with the lateral transistor having the conventional structure.

Accordingly, the hot carriers are not trapped in the LOCOS oxide film 12 at the side of the base region 4 so much, and the potential decrease near the top surface of the base region 4 can be further controlled, thus also in this point, the result to prevent the depletion layer 20 from expanding moreover can be obtained.

Like this, in the lateral transistor according to the present invention, the expansion of the depletion layer 20 near the top surface at the side of the base region 4 in the base-collector junction can be controlled, thus it is possible to prevent the base current from decreasing chronologically (increasing chronologically as for the current gain rate), and thus the lateral transistor having a higher quality can be provided.

Moreover, also in an aspect of manufacturing the lateral transistor, the polysilicon layer 14 has only to be formed in the determined part of the LOCOS oxide film 12, and furthermore, in case of forming it, a position displacement margin of the polysilicon layer 14 can also be left comparatively much, thus the lateral transistor of the present invention can easily be manufactured.

Besides, as the other embodiment of the lateral transistor according to the present invention, a lateral transistor having a structure in FIG. 7 can also be manufactured. That is to say, it is also applicable that the polysilicon layer 14 is manufactured further to cover the emitter region 6 completely, in other words, to be extended to be in contact with the emitter region 6.

Moreover, in the present invention, the polysilicon layer 14 is used for the composition as the electrode controlling the shapes of the depletion layers 20 and 23, however, it is also applicable to use the other conductor layer for the composition.

While the invention has been shown and described in detail, the foregoing description is in all aspects illustrative and not restrictive. It is therefore understood that numerous modifications and variations can be devised without departing from the scope of the invention.

What is claimed is:

1. A lateral transistor, wherein
an emitter region, a collector region and a base region are formed on an identical main surface of a substrate, comprising:
a field insulating film formed astride both on said collector region and on said base region; and
a conductor layer formed on said field insulating film, covering said collector region and said base region through said field insulating film from said collector region to the side of said emitter region, wherein
said emitter region and said conductor layer are electrically connected with each other.

2. The lateral transistor according to claim 1, further comprising:
an interlayer insulating film formed on said substrate; and
a wiring formed on said interlayer insulating film and connected with said emitter region and said conductor layer through a via hole placed in said interlayer insulating film.

3. The lateral transistor according to claim 1, wherein
said conductor layer is extended to be in contact with said emitter region.
